(19) United States
(12) Patent Application Publication
(10) Pub. No.: US 2006/0183027 A1
(43) Pub. Date: Aug. 17, 2006

(54) Novel method to form a microlens

(75) Inventors: Hua-Tai Lin, Hsin-Chu (TW); J. H. Chen, Hsin-Chu (TW); Chih-Kung Chang, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/060,197

(22) Filed: Feb. 17, 2005

(51) Int. Cl. H01L 31/0232

(52) U.S. Cl. 430/5; 430/321; 430/330; 257/432

(57) ABSTRACT

A method of manufacturing a microlens includes forming a photoresist layer over a substrate having a photo sensor located therein and exposing the photoresist layer in an exposure system having a lower resolution. The exposure uses a photomask having a microlens pattern comprising a plurality of dark regions and clear regions alternately disposed. The photoresist is developed to from the microlens having a curved shape.

### BACKGROUND

The present disclosure relates generally to micro-devices and, more specifically, to microlenses.

Microlens arrays are widely employed in image sensor technology, such as charged coupling device (CCD) image sensors and complimentary metal-oxide-semiconductor (CMOS) image sensors. In some examples, CCD, CMOS, and other types of microlens arrays transform a light pattern of pixels (e.g., an image) into an electric charge pattern.

Microlens arrays generally include polymer or dielectric microlenses. Polymer microlenses can be formed by patterning a polymer layer and subsequently thermal reflowing the patterned polymer layer to create the required shape of each microlens.

Difficulties often occur when pixel size is scaled down (pixel density is increased) and the processing window for forming the microlenses is narrowed down accordingly. Further, the thermal reflow process can cause neighboring microlenses to merge and/or may not produce an expected curvature due to the limited processing window.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1 through 3 illustrate sectional views of one embodiment of a microlens array during various fabrication stages.

FIG. 4 illustrates a top view of one embodiment of a photomask used to form the microlens array of FIGS. 1 through 3 constructed according to aspects of the present disclosure.

FIGS. 5a and 5b are plots of light intensity vs. distance showing an exposure light density distribution on a photoresist layer.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

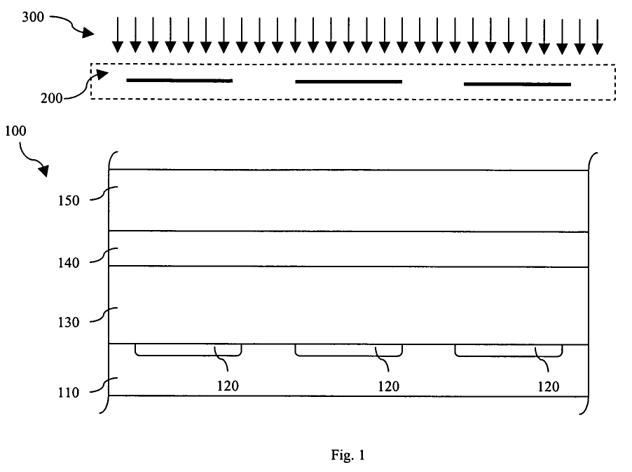

Referring to FIG. 1, one embodiment of a semiconductor chip 100 includes a microlens array constructed according to aspects of the present disclosure. The semiconductor chip may include a substrate 110 and photo sensors 120 formed therein.

The substrate 110 may comprise an elementary semiconductor such as silicon, germanium, or diamond. The substrate 110 may also comprise a compound semiconductor such as silicon carbide, gallium arsenic, indium arsenide, and/or indium phosphide. The substrate 110 may comprise an alloy semiconductor such as silicon germanium, silicon germanium carbide, gallium arsenic phosphide, and/or gallium indium phosphide. The substrate 110 may include an epitaxial layer. For example, the substrate may have an epitaxial layer overlying a bulk semiconductor. Further, the substrate may be strained for performance enhancement. For example, the epitaxial layer may comprise semiconductor materials different from those of the bulk semiconductor such as a layer of silicon germanium overlying a bulk silicon, or a layer of silicon overlying a bulk silicon germanium formed by a process such as selective epitaxial growth (SEG). Furthermore, the substrate 110 may comprise a semiconductor-on-insulator (SOI) structure. For examples, the substrate may include a buried oxide (BOX) layer formed by a process such as separation by implanted oxygen (SIMOX). The substrate 110 may comprise a p-type doped region and/or an n-type doped region. All doping may be implemented by a process such as ion implantation. The substrate 110 may comprise lateral isolation features to separate different devices formed on the substrate. In one embodiment, the substrate 110 may also include a doped epitaxial layer, a multiple silicon structure, or a multilayer, compound semiconductor structure.

The photo sensors 120 may be photodiodes and/or other sensors diffused or otherwise formed in the substrate 110. Aspects of the present disclosure are applicable and/or readily adaptable to microlens arrays employing charged coupling device (CCD) and complimentary metal-oxide-semiconductor (CMOS) image sensor applications (e.g., active-pixel sensors), among others. As such, the photo sensors 120 may comprise conventional and/or future-developed image sensing devices. Moreover, the photo sensors 120 may comprise color image sensors and/or monochromatic image sensors.

The semiconductor chip 100 may include a passivation layer 130. The passivation layer 130 may comprise silicon nitride (e.g., Si₃N₄), silicon oxynitride (e.g., Siₓ,N_{y}O_{z}), silicon oxide, silicon dioxide, and/or other materials. The passivation layer 130 may be substantially optically transparent, and may be formed by chemical vapor deposition (CVD), physical vapor deposition (PVD), atomic layer deposition (ALD), spin-on coating, and/or other processes. In one embodiment, the passivation layer 130 has a thickness ranging between about 1 μm and about 50 μm. The passivation layer 130 may further comprise a multilayer interconnect structure formed therein. The multilayer interconnect may include metal lines for lateral connections and via/contact features for vertical connections. The metal lines and via/contact features may be configured such that the photo sensors 120 may not be blocked thereby from incident light. The passivation layer 130 may have a multilayer structure such as a layer having the multilayer interconnects embedded therein and a layer to protect the underlying interconnects and the substrate.

The semiconductor chip 100 may include a dielectric layer 140. The dielectric layer 140 may comprise silicon nitride, silicon oxynitride, silicon oxide, silicon dioxide, and/or other materials. The dielectric layer 140 may also comprise a low-k dielectric layer having a dielectric constant less than or equal to about 3.9. The dielectric layer 140 may be formed by CVD, PVD, ALD, spin-on coating, and/or other processes. The dielectric layer 140 may have a multilayer structure including a planarization layer, color filter layer, and/or a spacer layer. The dielectric layer 140 may be formed by a method described above and may be substantially planar, possibly the result of chemical-mechanical-polishing (CMP). The color filters may be positioned such that the incident light is directed thereon and there through. In one embodiment, such color-transparent layers may comprise a polymeric material (e.g., negative photoresist based on an acrylic polymer) or resin. The color filter layer may comprise negative photoresist based on an acrylic polymer including color pigments. The spacer layer is formed to adjust the distance between the overlying microlens array and the underlying photo sensors 120. In one embodiment, the dielectric layer 140 has a thickness ranging between about 0.2 μm and about 50 μm.

A layer of photoresist 150 may be formed over the semiconductor chip 100 using a method such as spin-on coating. The layer of photoresist 150 may be pre-baked. The photoresist layer may then be exposed to a light source 300 through a photomask 200, wherein the photomask 200 is specially designed according to the present disclosure and is further described below.

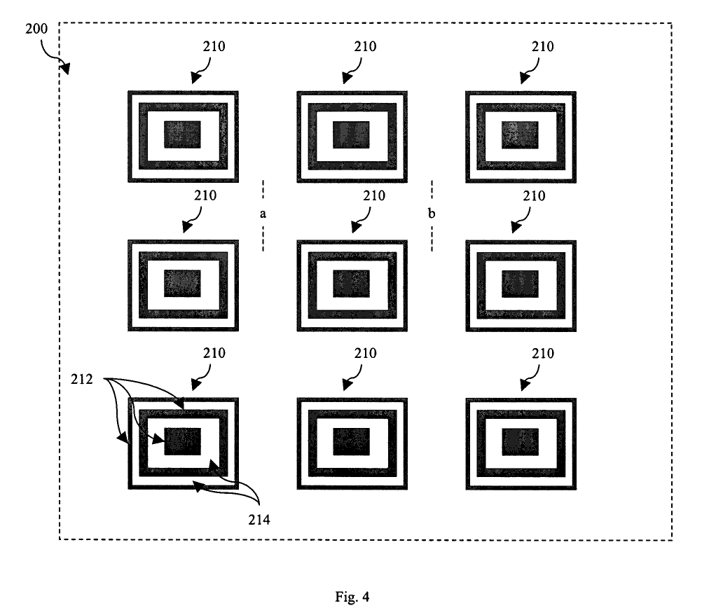

FIG. 4 illustrates a top view of one embodiment of the photomask 200 used to form the microlens array. The photomask 200 comprises a transparent substrate such as fused quartz or calcium fluoride and a layer of blocking material, opaque to the exposing light 300, such as a layer of chromium formed on the substrate. The layer of chromium is etched to form a pattern of the microlens array, wherein the pattern includes a plurality of dark areas where chromium remains and a plurality of clear areas where chromium is removed. The pattern of the microlens array in the photomask 200 may comprise a plurality of microlens patterns 210, each being not a complete dark area for positive photoresist (or a clear area for negative photoresist), instead comprising a plurality of dark regions 212 and a plurality of clear regions 214. The dark regions and clear regions may be configured and disposed, but not limited to, as strip, rectangular, polygon, and/or combinations thereof.

FIG. 4 illustrates one example of a microlens pattern 210 formed in the photomask 200, where the microlens pattern 210 comprises a plurality of strip-formed frame or square-dark regions. Other alternative structure may include rectangular array, parallel strips, and other proper features. The exposure system has a relative low resolution compared to dimensions of the plurality of dark regions and the plurality of clear regions. The width and/or separation of the strip, rectangular, or polygon array may be designed well below the minimum feature size of the exposure system in which the photomask 200 is used during a photolithography process. In this embodiment, the strips, rectangular, and polygons do not make clear images but instead function as assistant features, such that transmitted light 300 is averaged locally on the photoresist 150 during a photolithography process. The transmitted light density may depend on the dark ratio, which is defined as a quotient between the total dark area in a local region and the total area of the local region, and may have a value ranging from 1 (complete dark) to zero (complete clear). The transmitted light density may not be uniformly distributed and may be tuned to an expected profile by designing the pattern of the microlens having a proper dark ratio on each spot.

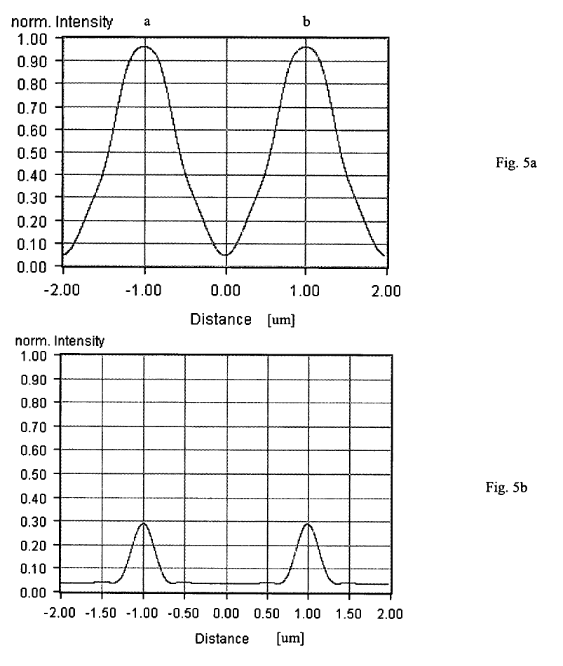

An example of the transmitted light density distribution through the photomask 200 and onto the layer of photoresist 150 is plotted in FIG. 5a in which the one-dimensional distribution corresponds to a line from point “a” to point “b” along one row of the array in the photomask 200 as labeled in FIG. 4. The transmitted light density has a smooth distribution, a broad intensity range (between an intensity threshold to change photoresist and highest intensity), and a slow slope of the intensity profile. Thus the transmitted light may be tuned to a proper level at each spot of the photoresist such that the spot is exposed at an expected dose. Comparatively, FIG. 5b is an exemplary plot of transmitted light density distribution on the layer of photoresist through a conventional photomask wherein a pattern of each microlens has a dark ratio of 1, defined within outlines of the microlens.

When the layer of photoresist 150 is exposed to the light source 300 under the photomask 200 during photolithography processing, the layer of photoresist may be exposed to different intensity levels at each local area, resulting in a curved surface after developing. For example, the microlens pattern may be designed to have a dark ratio from 1 at a center of the microlens pattern to 0.2 or 0.3 at the edge if a convex microlens is expected (and if the photoresist is positive).

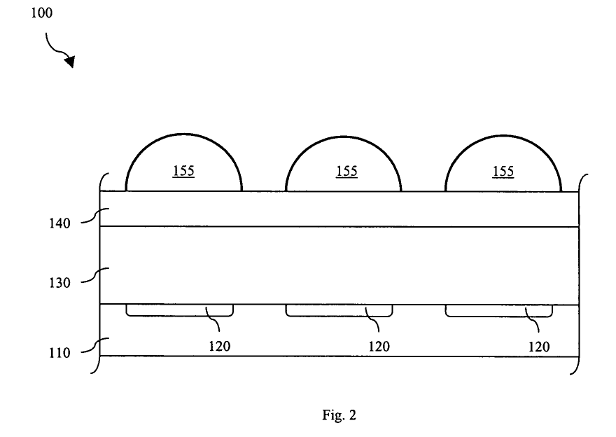

After the exposure process, the layer of photoresist 150 may be subject to post-exposure baking. The layer of photoresist 150 on the semiconductor chip 100 is then developed and a plurality of photoresist microlens 155 are formed, each having a curved shape such as a convex structure as illustrated in FIG. 2.

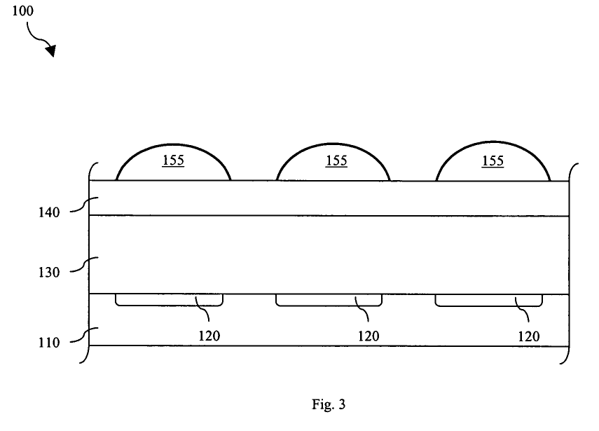

Since the curved shape is formed during the developing processing, a thermal reflow may be avoided, which is otherwise required to form a curved shape. Referring to FIG. 3, the semiconductor chip 100, the plurality of photoresist microlens 155 may be optionally annealed in a predefined temperature profile at a lower thermal expense than that of a thermal reflow. The annealing may have various functions including modifying the surface profile of the photoresist microlens 155, hardening, and/or baking the photoresist microlens 155. For example, the annealing process may reduce the curvature and smooth the surface of the photoresist microlens, as compared, for example, to the microlens 155 of FIG. 2. The annealing temperature and time may be dynamically tuned from lot to lot for optimized microlens profile and broaden processing window. In one example, the annealing temperature and time may range from about 80 degree to about 140 degree and from a few seconds to about one hour, respectively. In another example, the annealing process may be combined with baking process such as hard-baking process.

An example photolithography process may include photoresist patterning, etching, and photoresist stripping. The photoresist patterning may further include processing steps of photoresist coating, soft baking, mask aligning, exposing pattern, post-exposure baking, developing photoresist, and hard baking. Photolithography patterning may also be achieved or be replaced by other proper methods such as mask-less photolithography, electron-beam writing, ion-beam writing, and molecular imprint.

In one embodiment, the semiconductor chip 100 may further comprise an antireflective coating (ARC) layer formed underlying and/or overlying the layer of photoresist 150 for optimized exposing process.

Thus, the present disclosure provides a microlens device including, in one embodiment, a substrate having a photo sensor located therein and a microlens located over the substrate and including a substantially curved such as convex portion, substantially aligned over the photo sensor. The curved microlens is formed substantially by exposing a photoresist layer using a specially designed photomask. The photomask has an array of microlens patterns each comprising a plurality of dark regions and a plurality of clear regions designed in various feature including rectangular, strip, polygon, and other proper shape. The width and separation of the various features may be well below the minimum feature size of the exposure system in which the photomask 200 is used during a photolithography process. The microlens pattern may be designed and configured such that the local dark ratio changes associated with the expected surface curvature and profile of the photoresist microlens. The photoresist microlens may be formed during developing process.

The present disclosure also provides a method of manufacturing a microlens. The method includes forming a photoresist layer over a substrate having a photo sensor located therein and exposing the photoresist layer, in an exposure system having a lower resolution, using a photomask having a unique microlens pattern. In some embodiments, the microlens pattern includes alternating dark and clear regions. The exposed pattern of photoresist is then developed to from the microlens having a curved shape.

In another embodiment, a method of manufacturing a microlens comprises forming a photoresist layer over a substrate having a photo sensor located therein, pre-baking the photoresist layer, and exposing the photoresist layer in an exposure system. The exposure system uses a photomask having a microlens pattern comprising a plurality of dark regions and clear regions alternately disposed, each region having at least one dimension below the resolution of the exposure system. After exposure, the photoresist can be baked and developed to form the microlens having a convex profile.

In some embodiments, the photomask is designed such that each of the dark regions has at least one dimension below the resolution of the exposure system. The dark regions can be configured such that spaces there between are below the resolution of the exposure system. The dark regions can be designed such that the dark ratio gradually decreases from the center of the microlens pattern to the edge. The dark regions can be designed such that dark ratio is in compliance with an expected profile of the microlens pattern. The dark regions disposed within the microlens pattern may comprise a shape such as a stripe, rectangular, a polygon, and combinations thereof.

In some embodiments, the method further includes an annealing step after developing the photoresist layer. The annealing step modifies the curved shape of each microlens. The method may further include a baking process after forming the photoresist layer and a baking process after exposing the photoresist layer. The curved shape of the microlens may comprise a convex profile.

The present disclosure also provides a unique photomask. In one embodiment, the photomask includes a microlens pattern having a substrate transparent to an exposure light during an exposure process and a plurality of dark regions disposed within outlines of the microlens pattern. The plurality of dark regions are disposed such that spaces there between and at least one dimension of each are below the resolution of an exposure system during the exposure process.

The present disclosure also provides a unique microlens device with a substrate having a photo sensor located therein and a uniquely-shaped microlens including a substantially convex surface substantially aligned over the photo sensor.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of manufacturing a microlens, comprising:
forming a photoresist layer over a substrate having a photo sensor;
exposing the photoresist layer using a photomask having a microlens pattern comprising a plurality of dark regions and clear regions alternately disposed; and
developing the photoresist to from the microlens.

2. The method of claim 1 wherein the photomask is designed such that at least one of the plurality of dark regions has a dimension below a resolution of the exposure system.

3. The method of claim 1 wherein the photomask is designed such that at least one of the plurality of clear regions has a dimension below a resolution of the exposure system.

4. The method of claim 1 wherein the plurality of dark regions are designed such that their dark ratios gradually decrease from a center of the microlens pattern to the edge.

5. The method of claim 1 wherein the plurality of dark regions are designed such that their dark ratios are in compliance with an expected profile of the microlens pattern.

6. The method of claim 1 wherein the plurality of dark regions disposed within the microlens pattern comprises a shape selected from the group consisting of a stripe, rectangular, a polygon, and combinations thereof.

7. The method of claim 1 further comprising an annealing step after developing the photoresist layer.

8. The method of claim 7 wherein the annealing step modifies a curved shape of the microlens.

9. The method of claim 1 further comprising a pre-baking process after forming the photoresist layer.

10. The method of claim 1 further comprising a post-exposure baking process after exposing the photoresist layer.

11. The method of claim 1 wherein the microlens comprises a convex profile.

12. A photomask comprising:
a substrate transparent to an exposure light during an exposure process; and
a plurality of spaced dark regions disposed within individual microlens patterns of a microlens array pattern, wherein one of the plurality of dark regions and/or one of the spaces there between are below a resolution of the exposure process.

13. The photomask of claim 12 wherein the plurality of dark regions are designed such that their dark ratios gradually decrease from a center of a microlens pattern to an edge of the microlens pattern.

14. The photomask of claim 12 wherein the plurality of dark regions are designed to have a dark ratio in compliance with an expected profile of the microlens pattern.

15. The photomask of claim 12 wherein at least one of the plurality of dark regions comprises a shape selected from the group consisting of a stripe, rectangular, a polygon, a circle, an oval, and combinations thereof.

16. The photomask of claim 12 wherein the plurality of dark regions comprises chromium.

17. A microlens device, comprising:
a substrate having a photo sensor located therein; and
a microlens including a substantially convex surface substantially aligned over the photo sensor, and characterized by being formed by a photomask having a plurality of alternating dark and clear regions within a microlens pattern.

18. The microlens device of claim 17 further comprising:
a passivation layer having a multilayer interconnect structure disposed over the substrate; and
a dielectric layer disposed over the passivation layer.

19. The microlens device of claim 18 further comprising a color filter embedded in the dielectric layer.

20. A method of manufacturing a microlens, comprising:
forming a photoresist layer over a substrate having a photo sensor located therein;
pre-baking the photoresist layer;
exposing the photoresist layer, in an exposure system, using a photomask having a microlens pattern comprising a plurality of dark regions and clear regions alternately disposed, each region having at least one dimension below a resolution of the exposure system;
post-baking the photoresist layer;
developing the photoresist layer to from the microlens having a convex profile; and
annealing the microlens.
